(19) United States
(12) Patent Application Publication
(10) Pub. No.: US 2017/0324016 A1
(43) Pub. Date: Nov. 9, 2017

(54) HIGHLY-INTEGRATED THERMOELECTRIC COOLER

(71) Applicant: RESEARCH TRIANGLE INSTITUTE, Research Triangle Park, NC (US)

(72) Inventors: Philip BARLETTA, Cary, NC (US); Brian GRANT, Raleigh, NC (US); Erik Paul VICK, Raleigh, NC (US); Christopher GREGORY, Chapel Hill, NC (US)

(73) Assignee: RESEARCH TRIANGLE INSTITUTE, Research Triangle Park, NC (US)

(21) Appl. No.: 15/585,428

(22) Filed: May 3, 2017

Related U.S. Application Data
(60) Provisional application No. 62/330,992, filed on May 3, 2016.

(51) Int. Cl. H01L 35/30; H01L 35/32; H01L 35/18; H01L 35/34; H01L 35/16

(52) U.S. Cl. CPC H01L 35/30; H01L 35/34; H01L 35/16; H01L 35/18; H01L 35/32

(57) ABSTRACT

A method of forming a thermoelectric device structure and the resultant thermoelectric device structure. The method forms a first pattern of epitaxial thermoelectric elements of a first conductivity type on a first semiconductor substrate, forms a second pattern of epitaxial thermoelectric elements of a second conductivity type on a second semiconductor substrate, separates the epitaxial thermoelectric elements of the first conductivity type and places the epitaxial thermoelectric elements of the first conductivity type and the epitaxial thermoelectric elements of the second conductivity type on a heat sink, and integrates the heat sink to a device substrate including an electronic device to be cooled.

### CROSS REFERENCE TO RELATED APPLICATIONS

This application is related and claims priority under 35 U.S.C. 119(e) to U.S. Ser. No. 62/330,992; Attorney Docket No. 467285US, entitled “HIGHLY-INTEGRATED THERMOELECTRIC COOLER,” filed May 3, 2016, (the entire contents of which are incorporated herein by reference).

### BACKGROUND OF THE INVENTION

### Field of the Invention

The present invention is related to a method, procedure, and system for the fabrication of thin-film thermoelectric devices to be used in various cooling applications.

### Description of the Related Art

Thermoelectric coolers (TECs) are an effective technology for managing heat loads in high-performance electronic components. Thermoelectric cooling operates via the Peltier effect, a phenomenon in which a temperature difference is created by applying a voltage between two electrodes connected by a semiconductor (typically Bi₂Te₃, or a related material). In comparison with competing technologies, such as Stirling coolers, TE devices are smaller, lighter and have no moving parts. Several commercial manufacturers produce TE devices for cooling applications. Such devices are typically made of bulk materials with millimeter-scale thicknesses.

While most TECs are fabricated using bulk thermoelectric (TE) materials, thin-film thermoelectrics have been shown to be a viable alternative. Recently, progress has been achieved in the area of TE materials and devices based on thin films. Highly specialized metalorganic chemical vapor deposition (MOCVD) can provide state-of-the art n-type and p-type TE materials that range from a few nanometers to over 20 microns in thickness. These films can be processed into TE coolers (TECs), appropriately scaled to match the required specifications. These thin-film TE coolers (TFTECs) have been shown to have several advantages compared to the more widespread bulk-based TECs, such as reduced form factor and improved heat pumping. In fact, recent experimental results have shown that TFTECs can achieve heat pumping values in excess of 250 W/cm² at a temperature difference (ΔT) of 0K, which is over 25 times higher than that typically seen in bulk-based TECs at ΔT=0K.

Accordingly, thin thin-film TE devices (TFTECs) have several advantages compared to bulk, such as reduced form factor and improved heat pumping. However, the currently used TFTEC fabrication process and the resultant device configurations do not take full advantage of the thin-film nature of the TE materials.

The following references (the entire contents of which are incorporated herein by reference) describe conventional thin film thermoelectric materials and devices.
[1] Mahajan, R. et al. Cooling a microprocessor chip. Proceedings of the IEEE 94, 1476-1486 (2006).
[2] Prasher, R. S. et al. Nano and micro technology-based next-generation package-level cooling solutions. Intel Tech. J. 9, 285-296 (2005).
[3] Meysenc, L. et al. Power electronics cooling effectiveness versus thermal inertia. IEEE Trans. Power Electron. 20, 687-693 (2005).
[4] Joo Goh, T. et al. Thermal investigations of microelectronic chip with non-uniform power distribution: [5temperature prediction and thermal placement design optimization. Microelec. Internat. 21, 29-43 (2004).
[5] I. Chowdhury, I. et al. On-chip cooling by superlattice-based thin-film thermoelectrics. Nature Nanotech. 4, 235-238 (2009).
[6] R. Venkatasubramanian, et al. “Thin-film thermoelectric devices with high room-temperature figures of merit.” Nature, vol. 413, pp. 597-602 (2001).
[7] G. Bulman, P. Barletta, et. al. “Superlattice-based Thin-Film Thermoelectric Modules with High Cooling Fluxes.” Nat. Comms. DOI 10.1038/NCOMMS10302 (2016).

### SUMMARY OF THE INVENTION

In one embodiment of the present invention, there is provided a method of forming a thermoelectric device structure. The method forms a first pattern of epitaxial thermoelectric elements of a first conductivity type on a first semiconductor substrate, forms a second pattern of epitaxial thermoelectric elements of a second conductivity type on a second semiconductor substrate, separates the epitaxial thermoelectric elements of the first conductivity type, separates the epitaxial thermoelectric elements of the second conductivity type. The method places the epitaxial thermoelectric elements of the first conductivity type and the epitaxial thermoelectric elements of the second conductivity type on a heat sink, and joins the heat sink including the epitaxial thermoelectric elements of the first conductivity type and the epitaxial thermoelectric elements of the second conductivity type to a device substrate including an electronic device, wherein the electronic device is to be cooled by the epitaxial thermoelectric elements of the first conductivity type and the second conductivity type.

In one embodiment of the present invention, there is provided a thermoelectric device structure made by the method described above.

In one embodiment of the present invention, there is provided a thermoelectric device structure having a heat sink, epitaxial thermoelectric elements of a first conductivity type and epitaxial thermoelectric elements of a second conductivity type disposed on the heat sink; and a device substrate including an electronic device to be cooled by the epitaxial thermoelectric elements of the first conductivity type and the second conductivity type, wherein the device substrate has on a backside thereof metal patterns to interconnect the epitaxial thermoelectric elements of the first conductivity type to the epitaxial thermoelectric elements of a second conductivity type.

It is to be understood that both the foregoing general description of the invention and the following detailed description are exemplary, but are not restrictive of the invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic of a conventional TFTEC;

FIG. 2 is a depiction of initial steps in the HITEC fabrication process;

FIG. 3 is a depiction of subsequent steps in the HITEC fabrication process;

FIG. 4 is a depiction of subsequent steps in the HITEC fabrication process;

FIG. 5 is a depiction of subsequent steps in the HITEC fabrication process;

FIG. 6 is a depiction of subsequent steps in the HITEC fabrication process;

FIG. 7 is a depiction of subsequent steps in the HITEC fabrication process;

FIG. 8 is a depiction of subsequent steps in the HITEC fabrication process;

FIG. 9A schematic comparison of the conventional state of the art and that the HITEC architecture.

FIG. 9B is a side-view depiction of a HITEC device (not to scale);

FIG. 10 is a depiction of a single-couple HITEC composed of p- and n-type legs, according to one embodiment of the present invention; and

FIG. 11 is a comparison of the temperature difference ΔT measured between the hot side and cold side of a thermoelectric device fabricated on a Si substrate as compared to a traditional thermoelectric device fabricated an AlN substrate.

### DETAILED DESCRIPTION OF THE INVENTION

The amount of heat generated by present-day high-performance electronic components often results in unacceptably high operation temperatures and reduced component lifetimes. The heat load issue affects a variety of semiconductor circuits: from quantum cascade lasers to servers in data centers to electronic engine control units in military aircraft. Government, industry, and academia are all currently searching for reliable, effective means to address this issue.

The TFTEC fabrication process noted above in the background is, however, time and labor intensive, as the individual TE couples are fabricated as stand-alone subcomponents one die at a time. This makes TFTECs less attractive for volume manufacturing. Moreover, the current TFTEC fabrication technique makes inefficient use of the costly thin-film Bi₂Te₃-based materials, as over 80% of the epitaxial material is typically lost during post-growth processing.

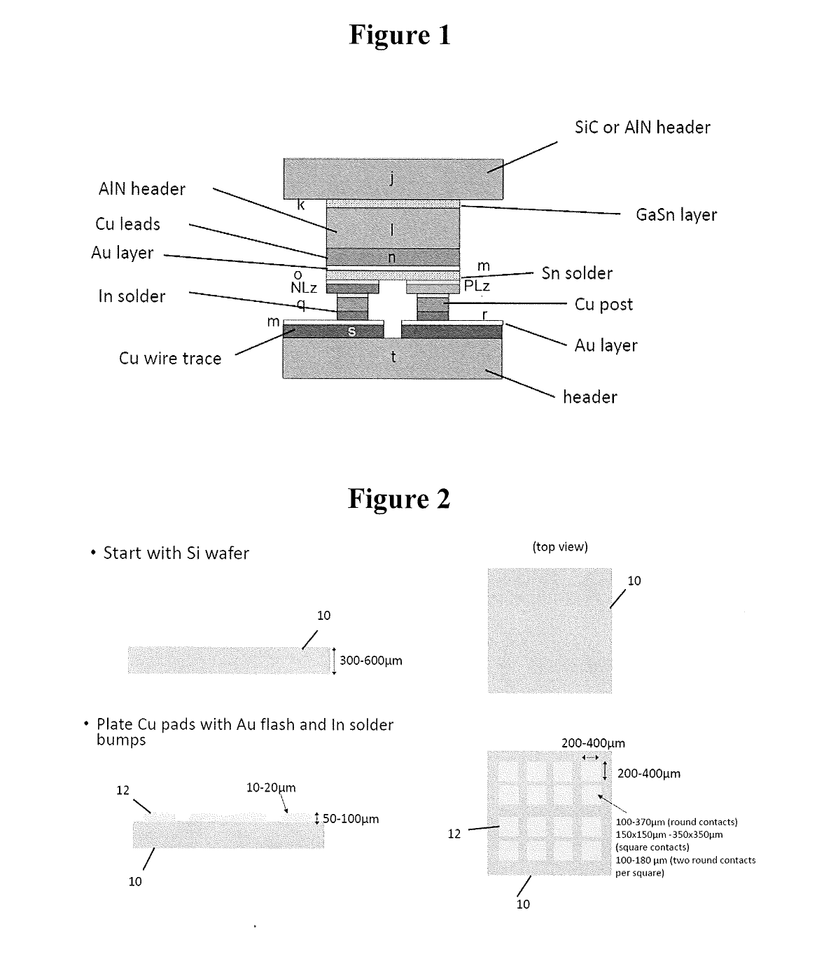

Another issue with the conventional TFTEC structure is the large number of extra layers required, in addition to the active TE materials q. This issue is illustrated in FIG. 1 (not to scale). FIG. 1 shows (beyond the pair of thermolectrics NL_{z} and PL_{z}) a number of dielectric headers and wiring interconnects (i.e., remaining or parasitic layers). In one embodiment of the invention, the bulk of the thermal resistance would preferably resides in the active n- and p-type layers NL_{z} and PL_{z}, indicated in FIG. 1. Yet, the interfaces and the remaining layers have been found by the inventors to represent a substantial thermal resistance.

As illustrated in FIG. 1, those layers (with associated interfaces) include the following: (j) is a 500 μm thick SiC or AlN header that is used for heat spreading in multi-die modules; (1) and (t) are 250-500 μm dielectric aluminum nitride (AlN) headers used for structural support and heat spreading; (k) is a 5 μm thick liquid GaSn layer used for thermal contact; (n) and (s) are 40 μm thick Cu leads used for carrying current to and from the active TE layers; (m) is a 0.5 μm thick Au layer used to prevent oxidation on traces (n) and (s); (o) is a 25 μm thick layer of Sn solder used to bond TE materials NL_{z} and PL_{z} to metal trace (n); (q) are 40 μm copper posts used to spatially separate the TE materials NL_{z} and PL_{z} from the bottom header (t); and (r) are In solder contacts used to electrically connect posts (q) to metal traces (s). TE materials NL_{z} and PL_{z} are contacted to the external circuit elements via evaporated, electroplated, or sputtered contact metals.

These layers and interfaces contribute significant thermal parasitics to the overall structure, and have been shown by the inventors to limit the device performance. Specifically, the inventors have discovered through modeling that 19% of the thermal resistance in a standard TFTEC device is due to these parasitic layers.

According to one embodiment of the invention, at least one improvement over conventional TFTEC structures minimizes the number and thickness of these extraneous, passive layers. According to one embodiment of the invention, at least one improvement over conventional TFTEC structures provides a wafer-scale TFTEC fabrication process that is attractive for volume manufacturing and which maximizes the use of the costly Bi₂Te₃-based epitaxial material. According to one embodiment of the invention, at least one improvement over conventional TFTEC structures is found in the provision of an architecture in which the thin film thermoelectric is fully integrated with the electrical component to be cooled. This integrated architecture (i.e., the HITEC structures of the invention) minimizes the parasitics associated with the extraneous dielectric and metallic layers and thermal interfaces noted above. According to one embodiment of the invention, this inventive approach provides for lower-profile cooling devices that can fit into narrower openings, when compared to conventional TFTECs. In one example of the HITEC device, the total height is less than 500 μm. In one example of the HITEC device, the total height is less than 200 μm. In one example of the HITEC device, the total height is less than 100 μm. In one example of the HITEC device, the total height is less than 50 μm. Moreover, according to one embodiment of the invention, the HITEC devices can be manufactured in such a way as to maximize usage of costly Bi₂Te₃-based epitaxial material, as explained below.

Growth of HITEC Thermoelectric Materials

The parameters, the layers, the materials, the dimensions, structural layout, and fabrication sequences listed below are only exemplary of the present invention and are not provided to limit the scope of the invention.

According to one embodiment of the invention, thermoelectric thin-film materials preferable for the HITEC devices include one or more p-type Bi₂Te₃ or Sb₂Te₃-based epitaxial materials, and one or more n-type Bi₂Te₃-based epitaxial materials. Both materials can be grown heteroepitaxially via metal organic chemical vapor deposition (MOCVD) on semi-insulating (100) GaAs substrates off-cut by 2° toward [110]. The n-type δ-doped structure is grown by periodically interrupting the growth of Bi₂Te₃ₓ Seₓ and dosing the flow with Te and Se species. According to one embodiment of the invention, the δ-doping process results in an increase in carrier concentration without a reduction in electron mobility, resulting in higher values of the thermoelectric figure of merit, ZT, and better cooling as compared to conventional Bi₂Te₃₋ₓ Seₓ structures.

While these superlattices and δ-doping structures are preferred, other thermoelectric materials of different sizes and semiconductor compositions (and doping) can be used in the HITEC devices of the present invention. Manufacturing using these different materials and constructions would follow similar procedures below which minimize the parasitic components and therefore result in high performance than compared to earlier approaches with those materials. Other suitable semiconductor and doping systems suitable for the present invention include for example semiconductor layers of alloyed thermoelectric materials.

Fabrication Process

According to one embodiment of the invention, the following HITEC process steps are preferred. FIG. 2 is a depiction of steps in the HITEC fabrication process. As shown in FIG. 2, metal traces are deposited onto a heat sink. The heat sink can be silicon, silicon carbide, or any other material with an electrically insulating surface. The thickness of the traces is preferably between 10 and 20 μm. If the heat sink 50 is electrically conductive, electrically insulating thin films of Si₃N₄ or SiO₂ can be used to isolate the metal traces or electrical routing from the electrically conductive heat sink.

In general, in this invention, a heat sink can be for example a substrate generally thicker and wider than the thin films or active heat source in which the heat sink is in thermal contact with. The heat sink (or often referred to in the literature and herein as a heat spreader) is used to conduct heat across a thickness thereof to a device which then can expel the heat into the environment. For example, heat sinks in the present invention can couple heat from one place in a thermal circuit to another and eventually into a cooling fluid (such as a forced gas or liquid flow) where the heat is taken away the thermal circuit. Diamond, silicon, copper, aluminum, and aluminum nitride are conventional types of heat sinks which can be used in the present invention.

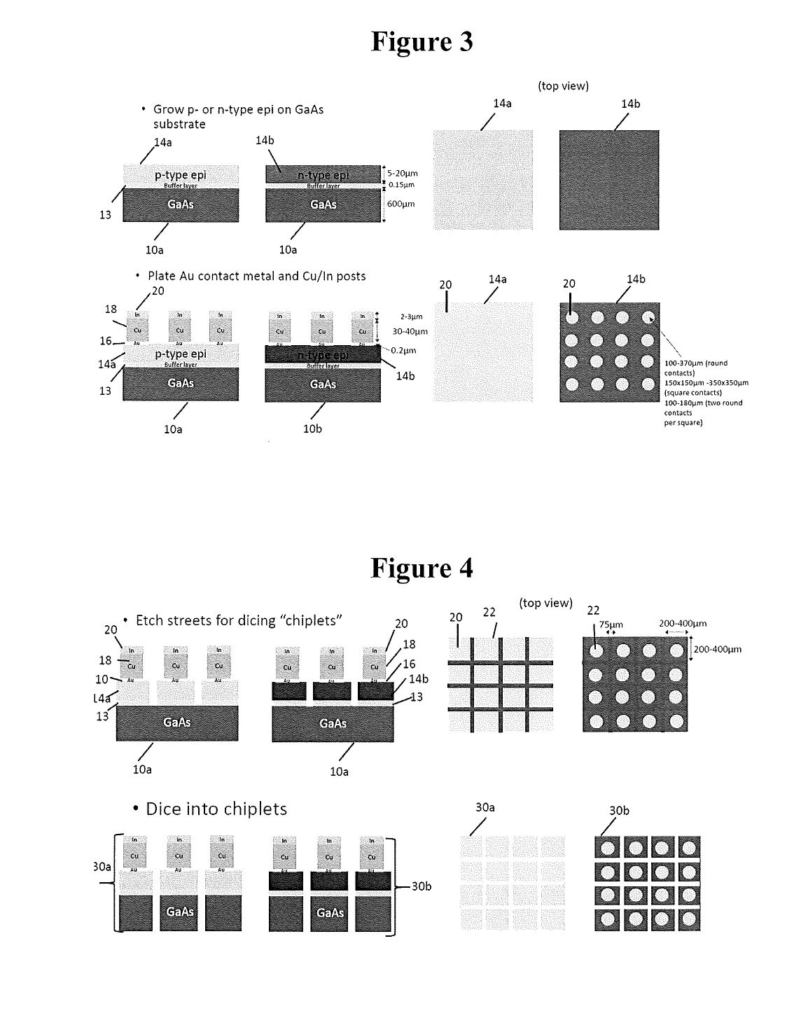

In parallel to the heat sink trace fabrication, the thermoelectric material is epitaxially grown on GaAs substrates separate from the heat sink. FIG. 3 depicts this process in detail as carried out on separate substrates 10a and 10b to form respectively the p-type and n-type thermoelectric elements 14a and 14b. In particular, FIG. 3 shows the growth of a buffer layer 13 on both GaAs substrates 10a and 10b. In one embodiment of the invention, the buffer layer 13 is Bi₂Te₃. Buffer layer is not necessarily limited to this material. Other material systems can be used which can grow epitaxially from the base substrate and be formed of a material which is resistant to etchants which etch the base substrate.

Following growth of the buffer layer 13, epitaxial p-type layers 14a and epitaxial n-type layers 14b are formed on the respective GaAs substrates. Afterwards, a gold (Au) contact layer 16 is formed and patterned over the epitaxial layers 14a and 14b. Cu posts 18 are formed above the Au layers 16, and In solder bumps 20 are formed on the Cu posts 18. The pattern of copper posts 18 each can have for example a 200 to 400 μm width. Other contact layers are also possible.

According to one embodiment of the invention, for deposition of the buffer layer 13 and the epitaxial layers 14a and 14b, organometallic trimethylbismuth, diisopropyltellurim, and trisdimethylaminoantimony can be used as the Bi, Te, and Sb sources, respectively, and gaseous hydrogen selenide can be used as the Se source. Other organometallic carriers may be used for the Bi, Te, and Sb. Organometallic carriers may also be used for the Se source. Growth temperature for these thin film thermoelectric materials can range from 375° C. to 425° C. However, hotter or colder temperatures are also possible.

While still in the wafer-form, these multilayer metal structures on substrates 10a and 10b are coated with a conformal coating (at thicknesses less than 5 μm). The preferred conformal coating is parylene-C. The wafers are then patterned using standard photolithography, and wet-etched using a HBr:Br₂:H₂O solution. After etching, the wafers are then diced into individual chiplets 30a and 30b as shown in FIG. 4. In one dicing example, the wafers were diced with a Keteca K2 blade (40 μm kerf, 760 μm clearance).

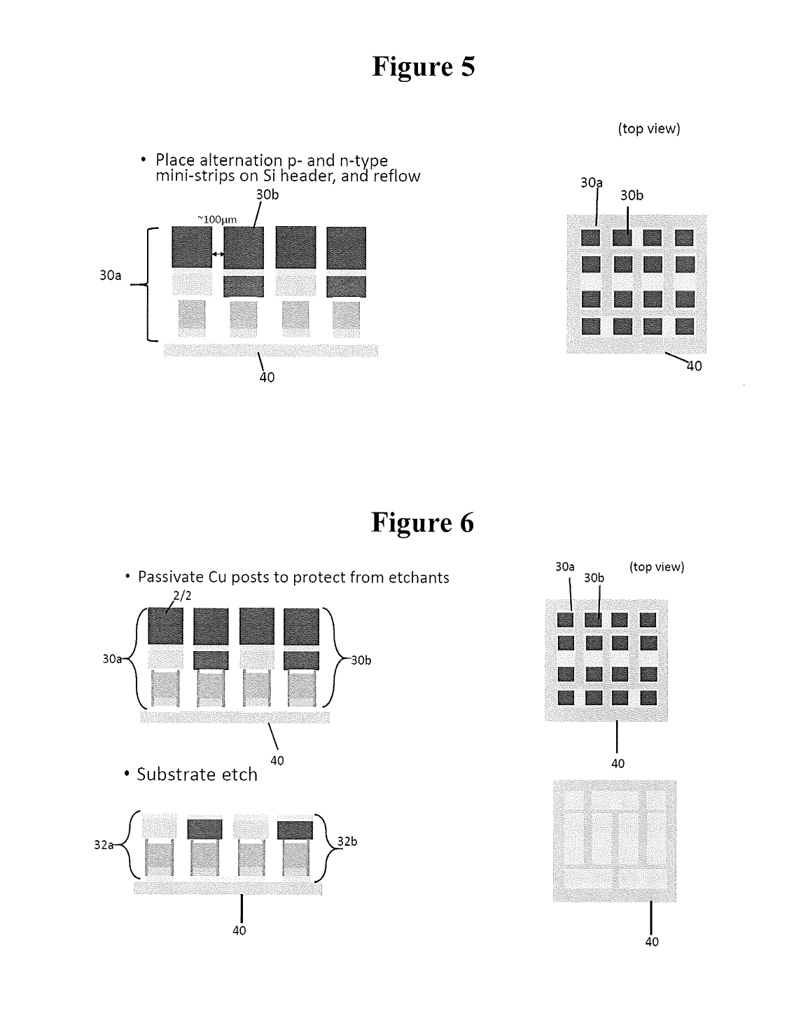

FIG. 5 shows individual p- and n-type TE wafers that have been processed into chiplets 30a and 30b using the HITEC fabrication technique described above and then arranged on another substrate 40 such as a silicon substrate. According to one embodiment of the invention, metal traces are deposited and patterned onto a wafer that serves as a heat sink. The n-type chiplets 30a are then bonded face down on the patterned traces on the heat sink 40, using an automated pick-and-place process. This process is then repeated for the p-type chiplets 30b, n-type and p-type chiplets that have been aligned and bonded to a heat sink. As shown in FIG. 5, the p-type chiplets 30a and the n-type chiplets 30b are placed alternately along strips on heat sink 40. Once the chiplets have been placed, the module is reflowed at 170° C. in a nitrogen atmosphere.

As shown in FIG. 6, once the p-type chiplets 30a and the n-type chiplets 30b (including parts of the epitaxial growth substrate) are placed and bonded on header 40, the Cu posts are passivated with a coating of parylene-C (not shown). An etchant of NH₄OH:H₂O₂ is used to etch the GaAs substrate material. The passivation coating protects the Cu posts during this etch.

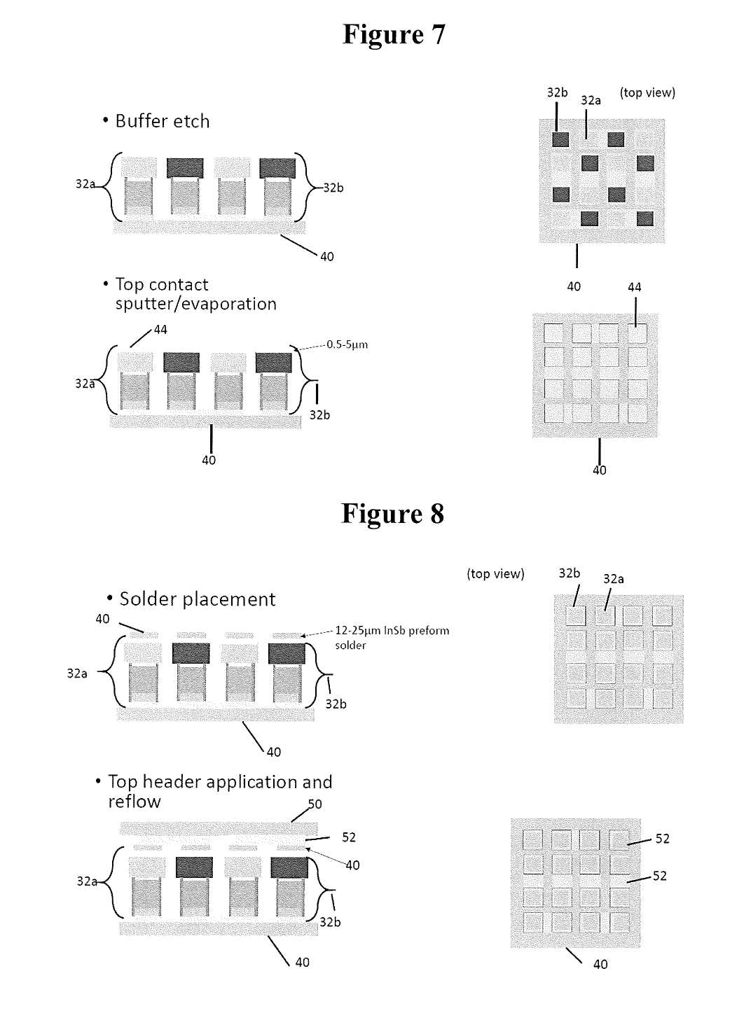

As shown in FIG. 7, an etchant of 1000:1 MeOH:Br₂ removes the buffer layer leaving micro-chiplets 32a and 32b (without the GaAs substrate material or buffer layer). Afterwards, a top contact 44 (composed of for example Cr/Ni/Au) is deposited on the top (exposed) surface of chiplets 32a and 32b.

Finally, as shown in FIG. 8, solder preforms 40 (e.g., 12-25 μm in thickness) are formed on the top side of the micro-chiplets 32a and 32b. A device containing wafer 50 having preformed metal routing lines 52 is placed and bonded by way of an InSn solder 40 onto the tops of the p-type micro-chiplets 32a and the n-type micro-chiplets 32b. The metal pattern formed on the backside of wafer 50 has a pattern matched to the Cu/Au posts, which completes the electrical routing between the p-type chiplets 32a and the n-type chiplets 32b to form a thermoelectric circuit. As noted above, if the heat sink 50 is electrically conductive, electrically insulating thin films of Si₃N₄ or SiO₂ can be used to isolate the electrical routing from the electrically conductive heat sink. Appropriate pressures and temperatures for the top header bonding include 130° C. reflow using for example a low temperature solder of InSn in for example a N₂ atmosphere.

Modeling of Parasitic Thermal Conductivity

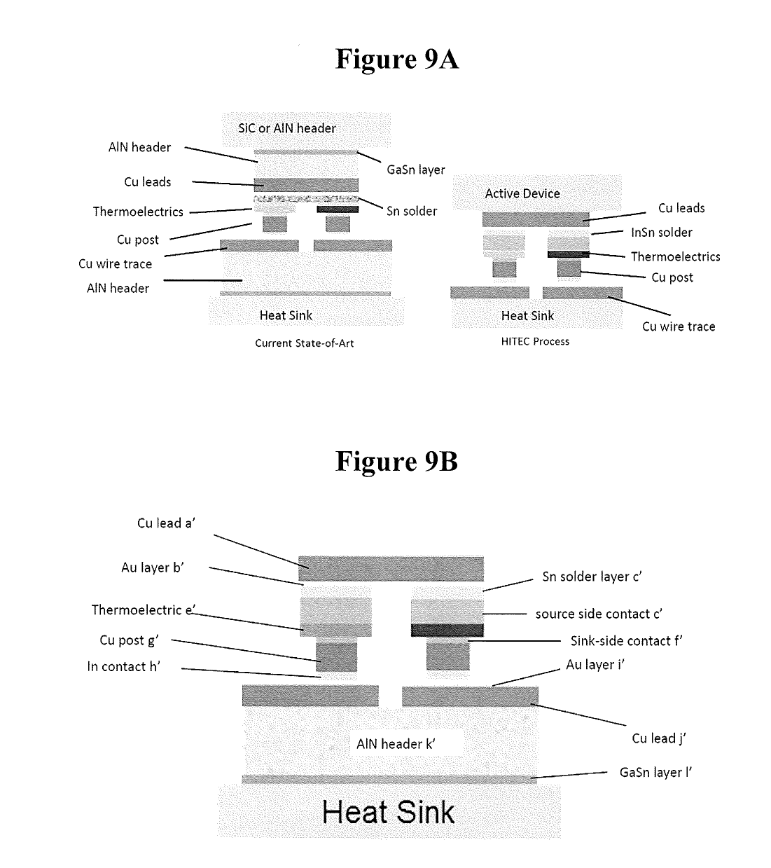

The inventors have analyzed the HITEC thermoelectric to determine its relative advantage over standard TFTEC designs by modeling the parasitic thermal resistance as a percentage of the total thermal resistance for both the standard and the HITEC devices. FIG. 9A schematic comparison of the conventional state of the art and that the HITEC architecture. This analysis was performed using standard thermal circuit analysis, with each linear thermal resistor element calculated as L/kA (Fourier's Law). Convection and radiation were assumed to be negligible, and electrical contact resistances were ignored, a reasonable assumption for the specific contact resistivity values in the 10⁻⁸ ohm-cm² range and below. The thermal and electrical consequences of the Thomson effect were also assumed to be negligible over the relevant temperature range. The total thermal resistance of each TEC architecture was assumed to be the sum of thermal resistances of (1) the p or n semiconductor material, (2) non-semiconductor structural/bonding elements, and (3) interfaces between heterogeneous materials in the architecture. Components 2 and 3 are parasitics. By adding the parasitic resistances and dividing this sum to the sum of all thermal resistances (parasitic plus semiconductor material), a proportion of thermal parasitics for both architectures is calculated. This analysis demonstrated that the percentage of thermal parasitics can be cut in half, from >19% when using traditional TFTEC designs to 9% when implementing the HITEC architecture. By modeling the parasitic thermal resistance as a percentage of the total thermal resistance for both the standard and the HITEC devices, the inventors have analyzed the HITEC thermoelectric architecture and have discovered its relative advantage(s) over conventional TFTEC designs. Indeed, the modeling shows that the substantial reduction in parasitics is a result of the removal of two thick (>200 μm) aluminum nitride structural headers, a bonding tin layer, and several thermal interfaces. These improvements reduced the total parasitic thermal circuit resistance from 9 K/W in a standard TFTEC to 4 K/W for a HITEC.

In one embodiment of the invention, the HITEC process allows for elimination of the Sn bond that connects the TE material to the source-side Cu trace; the top and bottom AN header; and elimination of the GaSn thermal interface material that mates the TE device to the heat the heat source and the heat sink. In one embodiment of the invention, the HITEC process eliminates the thermal interface resistances between these layers and adjacent layers. In one embodiment of the invention, the HITEC process allows for elimination of one or more intervening AlN heat spreaders conventionally used. See FIG. 9A and the discussion thereof below.

Hence, in one embodiment of the invention, there is provided a thermoelectric structure comprising a heat sink, active thermoelectric TE materials comprising epitaxial thermoelectric elements of a first conductivity type and epitaxial thermoelectric elements of a second conductivity type disposed on the heat sink, and a device substrate including an electronic device to be cooled by the epitaxial thermoelectric elements of the first conductivity type and the second conductivity type, In this embodiment, a percentage of thermal resistance that is due to parasitic thermal resistances other than a thermal resistance of the active TE materials can between 5 and 15% of total thermal resistance. In this embodiment, the percentage can be less than 12%, 10%, 8%, or 6%. In another embodiment, a percentage of thermal resistance that is due to parasitic thermal resistances other than a thermal resistance of the active TE materials can between 2 and 20% of total thermal resistance. In this embodiment, the percentage can be less than 18%, 16%, 14%, 12%, 10%, 8%, 6% or 4%.

### EXAMPLES

A prototype device built using a simplified version of the HITEC process was fabricated, and device-level ZT and hot side/cold side temperature difference (ΔT) were measured. The materials used in this device were the same or similar to those discussed elsewhere (e.g., p-type 10 Å/50 Å Bi₂Te₃/Sb₂Te₃ superlattices, and n-type δ-doped Bi₂Te₃₋ₓ Seₓ alloys).

This prototype device was a single p-n couple assembled to provide proof-of-concept of the HITEC process. The fabrication process varied from the full HITEC process shown in FIGS. 2 through 8 in several ways. First, it was built using small pieces of MOCVD-grown TE material on GaAs substrates, rather than full wafers. Second, the bottom traces were fabricated onto an AlN header, as in the standard TFTEC, rather than directly onto the heat sink. Third, there was no integrated heat source. The stack of the simplified, prototype HITEC device is shown in FIG. 9B. In FIG. 9B, the following components are depicted: (e′) represents the active thermoelectric material; (a′) and (j′) are 40 μm thick Cu leads used for carrying current to and from the active TE layers; (b′) and (I′) are 0.5 μm thick Au layers used to prevent oxidation on traces (a′) and (j′); (k′) is the 500 μm dielectric aluminum nitride (AlN) header used for structural support and heat spreading; (l′) is a 5 μm thick liquid GaSn layer used for thermal contact; (c′) are the source side contacts to the thermoelectric material, (f) are the sink-side contacts to the thermoelectric material, (g′) are 40 μm copper posts used to spatially separate the TE materials (e′) from the bottom header (k′); and (h′) are the In solder contacts used to electrically connect posts (g′) to metal traces (j′).

The device-level ZT measurement of this prototype TEC was carried out via the Harman ZT method. This technique involves a four-wire I-V measurement; with two probes supplying current to the device and two probes measuring the resultant voltage. This voltage, V_{T}, is the total voltage measured across the thermoelectric device at the given current. V_{T} is comprised of two components: the ohmic voltage (V_{R}) and the Peltier voltage (V₀). V_{R} is due to the ohmic resistance of the device, and V₀ is the thermally-generated voltage that is induced via the Seebeck effect. When the current is removed, the ohmic voltage decays almost instantaneously, while the Peltier voltage decays according to a thermal time constant. Thus, the individual values of V₀ and V_{R} can be discerned. The device ZT can then be calculated from the ratio of the Peltier voltage to the ohmic voltage; i.e, ZT=V₀/V_{R}.

In this work, the V₀ and V_{R} values were measured using BeCu probes. A 10 mA test current was supplied. Data was collected using a Tektronix TDS 1002 oscilloscope. All measurements were done in vacuum (P<10⁻⁴ Torr) to minimize thermal crosstalk between the hot and cold side of the device.

ΔT as a function of current for the prototype device was measured. The top and bottom TE module temperatures, T_{C} and T_{H}, respectively, were read using 25 μm diameter K-type thermocouples precisely positioned on the module. The measurements were taken under vacuum (P<10⁻⁴ Torr) to minimize convective parasitics. The TE device was sunk to a water-cooled heat sink which was maintained at 25° C.

Using these measurement techniques, a device-level ZT of 0.60 and ΔTₘₐₓ of 41.5K were measured for the prototype HITEC device. Although these values themselves are not exceptional (typical ΔTₘₐₓ values for standard TFTECs built with this material are ˜55K), these values do show that the HITEC process can produce a viable cooling device.

In one embodiment of the invention, delta-doping can further enhance the figure of merit of the thermoelectric layers and thus the COP of the TFTEC system. In this embodiment, Te-only δ-doped alloy Bi₂Te₃ₓSeₓ for n-type, Bi δ-doped Sb₂Te₃ for p-type) can be used for thermoelectric layers of ˜5 μm in thickness. Metal organic chemical vapor deposition (MOCVD) can be used to grow the n- and p-type materials δ-doped Bi₂Te₃₋ₓSeₓ alloy and Bi₂Te₃/Sb₂Te₃ superlattice, respectively. These layers can be grown from ≦1 to ˜25 μm in thickness and are subsequently processed into TECs. The HITEC process can be used for fabricating coolers using epitaxial thickness across the entire range.

The thickness of the epitaxial material is basically a design parameter—for high delta-T at low-or-zero heat flux, thicker material is considered better. However, for low delta-T, high heat flux applications, current is an important parameter. Decreasing thickness permits an increased current, and thus maximize heat pumping.

The basis for the larger cooling fluxes produced by thinner thermoelectric elements is the reduced electrical resistance of the thermoelectric structure, which in turn allows for the use of larger electrical currents. The higher currents produce more Seebeck heat pumping per unit area, as shown in the following equation

Q_{P}=S*T_{C}*I−0.5*I²*R−K(T_{H}−T_{C})=n*s*T_{C}*I−0.5*I²*(n*l*ρ/A)−(k*n*A/l)(T_{H}−T_{C})

where Q_{P} is the amount of heat pumped; S, R and K are the Seebeck coefficient, electrical resistance and thermal conductance of the thermoelectric module, respectively; T_{C} and T_{H} are the heat source and heat sink temperatures, respectively; I is electric current; n is the number of thermoelectric couples in the module; l is the thickness of one semiconductor leg; A is the cross-sectional area of one semiconductor leg (n and p are assumed to have identical geometry); and s, rl/A and kA/l are the per-couple Seebeck coefficient, electrical resistance and thermal conductance, respectively. This equation does not consider the parasitic thermal and electric resistance in the module.

The input electrical current that corresponds to the case of max Q_{P} can be calculated from the first derivative of the Q_{P}=f(I) function and is equal to ST_{C}/R. For bulk thermoelectric modules, the maximum value of Q_{P} is low, because bulk thermoelectric material cannot be thinned below a thickness of few hundred microns, limiting the maximum current due to the high module electric resistance R. The electrical current limitation results in bulk thermoelectric heat-pumping capabilities in the 1-10 W/cm² range. Epitaxial semiconductor films can be grown much thinner (for example, hundreds of nm), decreasing the electrical resistance and allowing larger electrical currents producing much higher cooling fluxes. For any given reduction in l by a factor of a, optimized I will increase by a. With all other things being equal, the cooling flux can be increased by a factor of 2, 5, or 10 times simply by decreasing the film thickness by a factor of 2, 5 or 10 times and increasing the electrical current accordingly.

According to one embodiment of the invention, cooling fluxes, on the order of several hundred W/cm², can be achieved by the use of thin thermoelectric material.

Another factor related to performance of the HITEC system of the invention is that the TE device is preferably operated at an electrical current value that ensures that the pumping power (STI) remains far greater than the sum of Ohmic and Fourier losses. The thermal conductance K will double as the electrical resistance Re is halved (e.g., because TE thickness was halved). In order to keep the same ΔT_{TEC} as existed prior to the doubling of K, then electric current must be doubled to ensure that pumping gains are increasing at least as fast as Fourier (and Ohmic) losses. Although counterintuitive, it is acceptable that Fourier (and Ohmic) losses continue to increase as TE material is thinned down because the corresponding choice to increase electrical current (which was the motivation to thin the TE material in the first place) increases the pumping term (STI) linearly, offsetting and exceeding the negative effects of the loss terms. The modelling has verified this unexpected performance at thinner TE layers, and has shown that the Fourier losses do not “run away” when the TE material is thinned down because heat-pumping gains increase faster than the KΔT_{TEC} losses.

As noted above, the demonstrated results have been for a semiconductor TE layer thicknesses of approximately 7 μm. By further reducing the epitaxial thickness to 1-3 μm, modeling suggests that heat fluxes approaching 1,500 W/cm² at ΔT_{TEC}=0 can be achieved and that loaded (i.e., ΔT_{TEC}>0 K) heat fluxes in the high hundreds are achievable in circumstances in which source and sink thermal resistances are sufficiently low. Accordingly, in one embodiment of the invention, the HITEC system can cool with heat fluxes ranging from 0 to 1,500 W/cm² at ΔT_{TEC}=0, and when under a heat load (i.e., ΔT_{TEC}>0 K) can cool with heat fluxes ranging from 0 to 500-1000 W/cm².

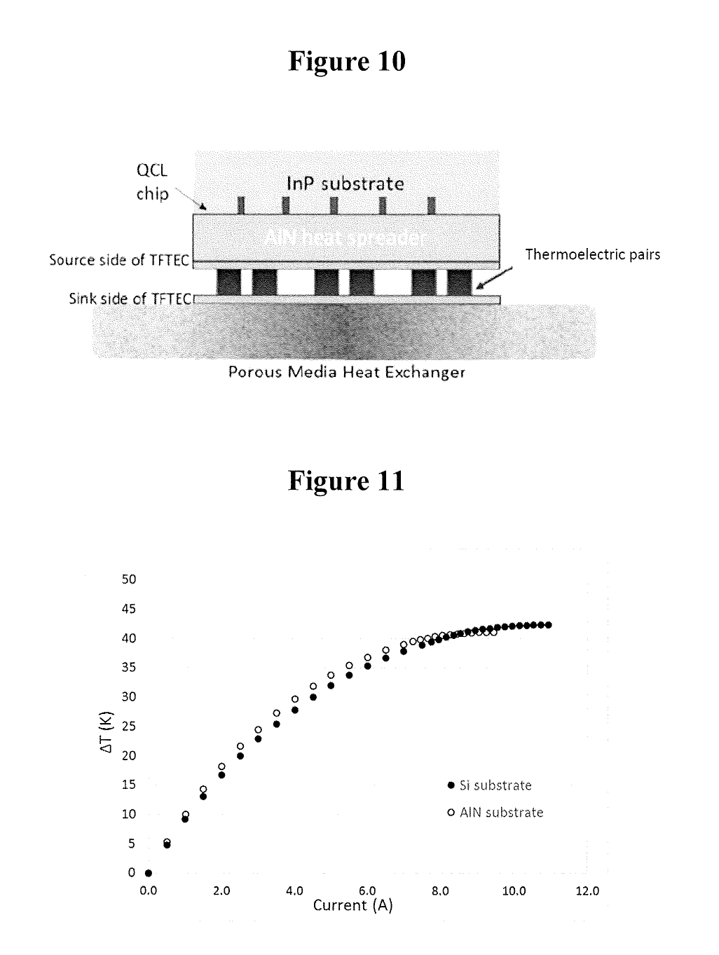

FIG. 10 is a depiction in which a quantum confined laser is being cooled the HITEC structure of the present invention coupled to a porous media heat exchanger. Porous media heat exchangers are known in the art. See for example U.S. Pat. No. 5,329,996 (the entire contents of which are incorporated herein by reference) which describes cooling structures for a high power density surface where a fluid is pumped along interconnected and continuous multiple channels on the backside of a sintered metal wick bonded to the cooled surface. The channels are located within a fluid layer which also includes multiple fluid holes, so that each hole is surrounded by interconnected channels. The holes in the '996 patent are connected to a manifold to collect or supply the pumped fluid. The channels in the '996 patent which surround each hole are connected to another manifold attached to the structure, and the proximity of the channels to the holes assures that fluid flow resistance within the sintered metal wick is minimized by the multiple short, wide paths. The '996 cooling structures are suitable as a heat sink in the present invention. See also for example U.S. Pat. No. 7,044,199 (the entire contents of which are incorporated herein by reference) which describes a heat exchanger including a base having a recess with a base coolant inlet opening and a base coolant outlet opening. A porous core of the '199 patent is positioned within the recess of the base, and has a core coolant inlet opening and a core coolant outlet opening that are arranged in corresponding relation with base coolant inlet opening and a base coolant outlet opening so as to be in fluid communication. A porous gasket of the '199 patent is pinched between the porous core and the base. The '199 heat exchanger are suitable as a heat sink in the present invention. Hence, in one embodiment of the invention, the HITEC system of the present invention utilizing a porous media heat exchanger keeps active devices (e.g., laser chips) at lower operating temperatures than would be possible with passive cooling alone.

Accordingly, in one embodiment of the invention, heat rejected from the hot side (i.e., sink side) of the TFTEC can be acquired by a pumped single-phase fluid in a Porous Metal Heat Exchanger (PMHX). In many heat exchanger applications, heat transfer is augmented when a low-conductance fluid is present through the use of extended surface area (i.e., fins). In many situations and suitable for the present invention, fins can provide additional surface area over which the fluid (for example from any source such as a forced air or liquid stream or from the micro-impinger) can exchange heat with the heat source. Fins are especially useful when the heat transfer coefficient produced by the flowing fluid is low, either because the fluid has low conductivity or because a thick thermal boundary layer develops on the available surfaces.

In one embodiment of the present invention, the PMHX is part of a closed pumped loop in which the cold coolant in pumped through a well-bonded matrix of small metal particles. The size of the metal particles are typically chosen in the range of 100 μm to 1,000 μm. The metal particles provide the surface area through which heat is removed by the pumped liquid. Because the liquid flows around each particle in the matrix in a tortuous path, thermal boundary layers do not develop appreciably on the surface of the particles so the local heat transfer coefficients are high. The surface area in a particle bed varies inversely with the particle diameter, so small particles can pack a large area into a small volume. This combination of high area and high local heat transfer coefficient on the particle surfaces makes it possible to extract high heat flux from the heat source as long as the particles are well-bonded to each other and to the primary heat transfer surface. While not limited to the following explanation, the simplest analogy is that where in a conventional finned heat exchanger the surface area is distributed through a volume in 2D fins, the PMHX has surface area that is distributed volumetrically in 3D, but with 5 to 10 times the surface area per unit volume. The effective heat transfer coefficient observed at the heat input surface is leveraged by large surface area on all the particles, and values of 50,000 to 300,000W/m²·K may be obtainable depending on the particulars of the PMHX.

Making the particles smaller helps to improve thermal performance; however, a reduced particle size comes with an increased hydraulic resistance. The pressure drop of the fluid flow through the PHMX is a strong function of the particle diameter and porosity of the particle. In one embodiment of the invention, the pressure drop in the PHMX is compensated by the use multiple parallel flow paths through the porous metal of the PHMX.

Additionally, experimental results by the inventors have shown that thermoelectric devices fabricated via a wafer scale processing on a silicon substrate (to which the thermoelectrics were bonded) have similar performance to those fabricated in the traditional method on an AlN substrate. FIG. 11 is a comparison of the temperature difference ΔT measured between the hot side and cold side of a thermoelectric device fabricated on a Si substrate as compared to a traditional thermoelectric device fabricated an AlN substrate.

For both devices depicted in FIG. 11, ΔT was measured as a function of current, where ΔT is the temperature difference measured between the hot side and cold side of the thermoelectric device. The maximum ΔT for the device fabricated wafer-scale on a Si substrate is 42.4K. The maximum ΔT for the device fabricated in the traditional method on an AlN substrate is 41.2K.

The data shows that the present invention has the distinctive advantage of being fabricated via a wafer scale process on a silicon substrate with no substantial drop in performance as compared to those fabricated using a traditional method on an AlN substrate.

Applications of the HITEC Device Structures

The inventive thermoelectric device structures of the present invention described above can be used in situations where large heat fluxes (e.g., greater than 100-500 W/cm²) need to be removed, although the inventive device structures are nevertheless useful at lower heat fluxes, as shown in the ranges noted above. Examples of where the thermoelectric device structure of the present invention can be used include, but are not limited to, quantum cascade lasers (e.g. used for infrared countermeasures), radio frequency (RF) switches, servers, advanced multicore signal processors, and RF power amplifiers.

Currently, this market need (if addressed by thermoelectric devices) is being filled by bulk thermoelectric devices. The inventive thermoelectric device structure represents an improvement because thin-film based thermoelectrics (a) pump heat better than bulk thermoelectric devices; (b) have fewer thermal parasitic layers than current bulk thermoelectric devices; and (c) can take advantage of standard CMOS integration technology for manufacture.

Quantum cascade lasers (QCL) are one particular field of application for the HITEC systems of the present invention, as illustrated in FIG. 10. QCLs are used in infrared countermeasure (IRCM) systems to combat man-portable air defense systems (MANPADS) or shoulder-launched, infrared (IR)-guided, surface-to-air missiles. For these counter-measure applications, QCL arrays produce tens of Watts of optical power in continuous wave (CW) and dissipate on the order of hundreds of Watts per cm². Although these heat fluxes can be removed by advanced passive coolers, the fact that the QCL efficiency decreases significantly with the temperature of the laser necessitates the use of active cooling to reduce the temperature rise.

Generalized Aspects of the Invention

The following numbered statements represent the generalized aspects of this invention.

1. A method of forming a thermoelectric device structure, comprising:

forming a first pattern of epitaxial thermoelectric elements of a first conductivity type on a first semiconductor substrate;

forming a second pattern of epitaxial thermoelectric elements of a second conductivity type a second semiconductor substrate, wherein the thermoelectric elements of the first and second patterns are spaced apart and wherein the first and second conductivity types are different;

separating the epitaxial thermoelectric elements of the first conductivity type;

separating the epitaxial thermoelectric elements of the second conductivity type;

placing the epitaxial thermoelectric elements of the first conductivity type and the epitaxial thermoelectric elements of the second conductivity type on a heat sink; and

joining the heat sink including the epitaxial thermoelectric elements of the first conductivity type and the epitaxial thermoelectric elements of the second conductivity type to a device substrate including an electronic device, wherein the electronic device is to be cooled by the epitaxial thermoelectric elements of the first conductivity type and the second conductivity type.

2. The method according to statement 1, wherein forming the first pattern of epitaxial thermoelectric elements comprises:

forming a first buffer layer on the first semiconductor substrate;

forming a first layer of a first epitaxial thermoelectric material of the first conductivity type on the first buffer layer of the first semiconductor substrate;

forming a second buffer layer on the second semiconductor substrate;

forming a second layer of a second epitaxial thermoelectric material of the second conductivity type on the second buffer layer of the second semiconductor substrate.

3. The method according to statement 2, wherein separating the epitaxial thermoelectric elements of the first conductivity type comprises dicing the first substrate, and wherein separating the epitaxial thermoelectric elements of the second conductivity type comprises dicing the second substrate.

4. The method according to statement 3, further comprising:

bonding the separated epitaxial thermoelectric elements of the first conductivity type and the separated epitaxial thermoelectric elements of the second conductivity type to the heat sink substrate;

removing material of the first substrate from the epitaxial thermoelectric elements of the first conductivity type; and

removing material of the second substrate from the epitaxial thermoelectric elements of the second conductivity type.

5. The method according to statement 4, further comprising:

forming wiring patterns on a back side of the device substrate; and

bonding the separated epitaxial thermoelectric elements of the first conductivity type and the separated epitaxial thermoelectric elements of the second conductivity type to the wiring patterns on the back side of the device substrate.

6. The method according to any of statements 1-5, wherein the epitaxial thermoelectric elements comprises bismuth telluride thermoelectric elements.

7. The method according to any of statements 1-6, wherein the substrate comprises a gallium arsenide substrate.

8. The method according to any of statements 1-7, wherein the electronic device of the device substrate joined to the heat sink substrate includes at least one of a diode, a transistor, and/or a sensor on the semiconductor substrate.

9. The method according to any of statements 1-8, wherein forming a first pattern of epitaxial thermoelectric elements comprises forming for the epitaxial thermoelectric elements a superlattice of Bi₂Te₃/Sb₂Te₃.

10. The method according to any of statements 1-8, wherein forming a second pattern of epitaxial thermoelectric elements comprises forming for the epitaxial thermoelectric elements an n-type δ-doped Bi₂Te₃ₓ Seₓ alloy.

11. A thermoelectric structure comprising:

a heat sink;

epitaxial thermoelectric elements of a first conductivity type and epitaxial thermoelectric elements of a second conductivity type disposed on the heat sink; and

a device substrate including an electronic device to be cooled by the epitaxial thermoelectric elements of the first conductivity type and the second conductivity type,

wherein the device substrate has on a backside thereof metal patterns to interconnect the epitaxial thermoelectric elements of the first conductivity type to the epitaxial thermoelectric elements of a second conductivity type.

12. The thermoelectric structure according to statement 11, wherein the epitaxial thermoelectric elements have no epitaxial growth substrate present.

13. The thermoelectric structure according to any of statements 11-12, wherein the epitaxial thermoelectric elements comprise bismuth telluride thermoelectric elements.

14. The thermoelectric structure according to any of statements 11-13, wherein the epitaxial thermoelectric elements comprise a superlattice of Bi₂Te₃/Sb₂Te₃.

15. The thermoelectric structure according to any of statements 11-14, wherein the epitaxial thermoelectric elements comprise a δ-doped Bi₂Te₃₋ₓ Seₓ alloy.

16. The thermoelectric structure according to any of statements 11-15, wherein the electronic device containing substrate comprises at least one of a diode, a transistor, and/or a sensor.

17. A thermoelectric structure comprising:

a heat sink;

one or more metallic posts;

epitaxial thermoelectric elements of a first conductivity type and epitaxial thermoelectric elements of a second conductivity type disposed in thermal contact with the heat sink;

one or more thin film metallic layers or thin film electrical isolation layers;

intervening between the heat sink and the one or more metallic posts or intervening between the thermoelectric elements and the heat sink;

said thermal contact with the heat sink comprising only the metallic posts and said one or more thin film metallic layers or thin film electrical isolation layers; and

a device substrate including an electronic device to be cooled by the epitaxial thermoelectric elements of the first conductivity type and the second conductivity type

18. A thermoelectric structure comprising:

a heat sink;

epitaxial thermoelectric elements of a first conductivity type and epitaxial thermoelectric elements of a second conductivity type disposed on the heat sink without an intervening heat spreader; and

a device substrate including an electronic device to be cooled by the epitaxial thermoelectric elements of the first conductivity type and the second conductivity type.

19. A thermoelectric structure comprising:

a heat sink;

epitaxial thermoelectric elements of a first conductivity type and epitaxial thermoelectric elements of a second conductivity type disposed on the heat sink; and

a device substrate including an electronic device to be cooled by the epitaxial thermoelectric elements of the first conductivity type and the second conductivity type,

wherein the device substrate is disposed in thermal contact with the epitaxial thermoelectric elements of the first and second conductivity types only via one or more thin film metallic layers or one or more thin film electrical isolation layers.

20. A thermoelectric structure comprising:

a heat sink;

epitaxial thermoelectric elements of a first conductivity type and epitaxial thermoelectric elements of a second conductivity type disposed on the heat sink; and

a device substrate including an electronic device to be cooled by the epitaxial thermoelectric elements of the first conductivity type and the second conductivity type,

wherein the device substrate is disposed in thermal contact with the epitaxial thermoelectric elements of the first and second conductivity types without an intervening heat spreader.

21. A thermoelectric structure comprising:

a heat sink;

active thermoelectric TE materials comprising epitaxial thermoelectric elements of a first conductivity type and epitaxial thermoelectric elements of a second conductivity type disposed on the heat sink; and

a device substrate including an electronic device to be cooled by the epitaxial thermoelectric elements of the first conductivity type and the second conductivity type,

wherein a percentage of thermal resistance that is due to parasitic thermal resistances other than a thermal resistance of the active TE materials is between 5 and 15% of total thermal resistance.

22. The structure of statement 21, wherein said percentage is less than 12%.

23. The structure of statement 21, wherein said percentage is less than 10%.

24. A thermoelectric device including any of the thermoelectric structures of statements 11-23.

25. A thermoelectric device made by the methods of any of statements 1-10, and including any of the thermoelectric structures of statements 11-23.

26. A thermoelectric device made by the methods of any of statements 1-10.

Numerous modifications and variations of the present invention are possible in light of the above teachings. It is therefore to be understood that within the scope of the appended claims, the invention may be practiced otherwise than as specifically described herein.

1. A method of forming a thermoelectric device structure, comprising:
forming a first pattern of epitaxial thermoelectric elements of a first conductivity type on a first semiconductor substrate;
forming a second pattern of epitaxial thermoelectric elements of a second conductivity type a second semiconductor substrate, wherein the thermoelectric elements of the first and second patterns are spaced apart and wherein the first and second conductivity types are different;
separating the epitaxial thermoelectric elements of the first conductivity type;
separating the epitaxial thermoelectric elements of the second conductivity type;
placing the epitaxial thermoelectric elements of the first conductivity type and the epitaxial thermoelectric elements of the second conductivity type on a heat sink; and
joining the heat sink including the epitaxial thermoelectric elements of the first conductivity type and the epitaxial thermoelectric elements of the second conductivity type to a device substrate including an electronic device, wherein the electronic device is to be cooled by the epitaxial thermoelectric elements of the first conductivity type and the second conductivity type.

2. The method according to claim 1, wherein forming the first pattern of epitaxial thermoelectric elements comprises:
forming a first buffer layer on the first semiconductor substrate;
forming a first layer of a first epitaxial thermoelectric material of the first conductivity type on the first buffer layer of the first semiconductor substrate;
forming a second buffer layer on the second semiconductor substrate;
forming a second layer of a second epitaxial thermoelectric material of the second conductivity type on the second buffer layer of the second semiconductor substrate.

3. The method according to claim 2, wherein separating the epitaxial thermoelectric elements of the first conductivity type comprises dicing the first substrate, and wherein separating the epitaxial thermoelectric elements of the second conductivity type comprises dicing the second substrate.

4. The method according to claim 3, further comprising:
bonding the separated epitaxial thermoelectric elements of the first conductivity type and the separated epitaxial thermoelectric elements of the second conductivity type to the heat sink substrate;
removing material of the first substrate from the epitaxial thermoelectric elements of the first conductivity type; and
removing material of the second substrate from the epitaxial thermoelectric elements of the second conductivity type.

5. The method according to claim 4, further comprising:
forming wiring patterns on a back side of the device substrate; and
bonding the separated epitaxial thermoelectric elements of the first conductivity type and the separated epitaxial thermoelectric elements of the second conductivity type to the wiring patterns on the back side of the device substrate.

6. The method according to claim 1, wherein the epitaxial thermoelectric elements comprises bismuth telluride thermoelectric elements.

7. The method according to claim 1, wherein the substrate comprises a gallium arsenide substrate.

8. The method according to claim 1, wherein the electronic device of the device substrate joined to the heat sink substrate includes at least one of a diode, a transistor, and/or a sensor on the semiconductor substrate.

9. The method according to claim 1, wherein forming a first pattern of epitaxial thermoelectric elements comprises forming for the epitaxial thermoelectric elements a superlattice of Bi₂Te₃/Sb₂Te₃.

10. The method according to claim 1, wherein forming a second pattern of epitaxial thermoelectric elements comprises forming for the epitaxial thermoelectric elements an n-type δ-doped Bi₂Te₃₋ₓ Seₓ alloy.

11. A thermoelectric structure comprising:
a heat sink;
epitaxial thermoelectric elements of a first conductivity type and epitaxial thermoelectric elements of a second conductivity type disposed on the heat sink; and
a device substrate including an electronic device to be cooled by the epitaxial thermoelectric elements of the first conductivity type and the second conductivity type,
wherein the device substrate has on a backside thereof metal patterns to interconnect the epitaxial thermoelectric elements of the first conductivity type to the epitaxial thermoelectric elements of a second conductivity type.

12. The thermoelectric structure according to claim 11, wherein the epitaxial thermoelectric elements have no epitaxial growth substrate present.

13. The thermoelectric structure according to claim 11, wherein the epitaxial thermoelectric elements comprise bismuth telluride thermoelectric elements.

14. The thermoelectric structure according to claim 11, wherein the epitaxial thermoelectric elements comprise a superlattice of Bi₂Te₃/Sb₂Te₃.

15. The thermoelectric structure according to claim 11, wherein the epitaxial thermoelectric elements comprise a δ-doped Bi₂Te₃₋ₓ Seₓ alloy.

16. The thermoelectric structure according to claim 13, wherein the electronic device containing substrate comprises at least one of a diode, a transistor, and/or a sensor.

17. A thermoelectric structure comprising:
a heat sink;
one or more metallic posts;
epitaxial thermoelectric elements of a first conductivity type and epitaxial thermoelectric elements of a second conductivity type disposed in thermal contact with the heat sink;
one or more thin film metallic layers or thin film electrical isolation layers intervening between the heat sink and the one or more metallic posts or intervening between the thermoelectric elements and the heat sink;
said thermal contact with the heat sink comprising only the metallic posts and said one or more thin film metallic layers or thin film electrical isolation layers; and
a device substrate including an electronic device to be cooled by the epitaxial thermoelectric elements of the first conductivity type and the second conductivity type

18. A thermoelectric structure comprising:
a heat sink;
epitaxial thermoelectric elements of a first conductivity type and epitaxial thermoelectric elements of a second conductivity type disposed on the heat sink without an intervening heat spreader; and
a device substrate including an electronic device to be cooled by the epitaxial thermoelectric elements of the first conductivity type and the second conductivity type.

19. A thermoelectric structure comprising:
a heat sink;
epitaxial thermoelectric elements of a first conductivity type and epitaxial thermoelectric elements of a second conductivity type disposed on the heat sink; and
a device substrate including an electronic device to be cooled by the epitaxial thermoelectric elements of the first conductivity type and the second conductivity type,
wherein the device substrate is disposed in thermal contact with the epitaxial thermoelectric elements of the first and second conductivity types only via one or more thin film metallic layers or one or more thin film electrical isolation layers.

20. A thermoelectric structure comprising:
a heat sink;
epitaxial thermoelectric elements of a first conductivity type and epitaxial thermoelectric elements of a second conductivity type disposed on the heat sink; and
a device substrate including an electronic device to be cooled by the epitaxial thermoelectric elements of the first conductivity type and the second conductivity type,
wherein the device substrate is disposed in thermal contact with the epitaxial thermoelectric elements of the first and second conductivity types without an intervening heat spreader.

21. A thermoelectric structure comprising:
a heat sink;
active thermoelectric TE materials comprising epitaxial thermoelectric elements of a first conductivity type and epitaxial thermoelectric elements of a second conductivity type disposed on the heat sink; and
a device substrate including an electronic device to be cooled by the epitaxial thermoelectric elements of the first conductivity type and the second conductivity type,
wherein a percentage of thermal resistance that is due to parasitic thermal resistances other than a thermal resistance of the active TE materials is between 5 and 15% of total thermal resistance.

22. The structure of claim 21, wherein said percentage is less than 12%.

23. The structure of claim 21, wherein said percentage is less than 10%.
